(19) United States
(12) Patent Application Publication
(10) Pub. No.: US 2014/0264958 A1
(43) Pub. Date: Sep. 18, 2014

(54) SEMICONDUCTOR PACKAGE, FABRICATION METHOD THEREOF AND MOLDING COMPOUND

(71) Applicant: Siliconware Precision Industries Co., Ltd., Taichung (TW)

(72) Inventors: Tsung-Hsien Hsu, Taichung Hsien (TW); Hsin-Lung Chung, Taichung Hsien (TW); Te-Fang Chu, Taichung Hsien (TW); Kwok-Yan Lam, Taichung Hsien (TW); Shao-Meng Sim, Taichung Hsien (TW)

(73) Assignee: Siliconware Precision Industries Co., Ltd., Taichung (TW)

(21) Appl. No.: 13/968,834

(22) Filed: Aug. 16, 2013

(30) Foreign Application Priority Data
Mar. 18, 2013 (TW) 102109431

(51) Int. Cl. H01L 23/29; H01L 21/56

(52) U.S. Cl. CPC H01L 23/295; H01L 23/291; H01L 21/56
USPC 257/788; 438/127; 252/519.33

(57) ABSTRACT

A semiconductor package is disclosed, which includes: a substrate body; a semiconductor element disposed on the substrate body; and a molding compound forms on the substrate body for encapsulating the semiconductor element. The molding compound contains a metal oxide so as to have a high insulation impedance and a high heat dissipating rate and be capable of suppressing electromagnetic interference.

### BACKGROUND OF THE INVENTION

1. Field of the Invention

The present invention relates to semiconductor packages, and more particularly, to a semiconductor package having a semiconductor chip encapsulated by a molding compound and a fabrication method of the semiconductor package.

2. Description of Related Art

In order to form a semiconductor package, a semiconductor chip is electrically connected to a carrier such as a lead frame or a packaging substrate, and an encapsulant made of such as an epoxy resin is formed on the carrier for encapsulating the semiconductor chip, thereby protecting the semiconductor chip against intrusion of external moisture or contaminants.

However, a semiconductor package in operation can easily be influenced by electromagnetic interference (EMI), thereby causing abnormal operation and poor electrical performance of the semiconductor package.

Accordingly, a semiconductor package having a metal shield embedded in the encapsulant thereof is disclosed. FIG. 1 is a cutaway view of the semiconductor package. Referring to FIG. 1, a semiconductor chip 11 is disposed on a carrier 10 and electrically connected to the carrier 10 through a plurality of bonding wires 12. A perforated metal shield 13 is disposed on the carrier 10 to cover the semiconductor chip 11 and the metal shield 13 is electrically connected to a ground terminal 100 of the carrier 10. A molding compound 14 is formed on the carrier 10 for encapsulating the metal shield 13 and the semiconductor chip 11. The molding compound 14 is further cured to form an encapsulant.

The metal shield 13 shields the semiconductor chip 11 from external EMI so as to prevent abnormal operation of the semiconductor package 1.

However, the fabrication and assembly of the metal shield 13 complicate the fabrication process and increase the assembly difficulty of the semiconductor package.

Further, during a molding process, when the molding compound 14 passes through the perforated metal shield 13 to encapsulate the semiconductor chip 11, turbulence easily occurs in the molding compound 14, thus easily resulting in generation of air bubbles or voids in the molding compound 14 and consequently causing a popcorn effect in a subsequent heating process.

Therefore, how to overcome the above-described drawbacks has become urgent.

### SUMMARY OF THE INVENTION

In view of the above-described drawbacks, the present invention provides a semiconductor package, which comprises: a substrate body; at least a semiconductor element disposed on the substrate body; and a molding compound formed on the substrate body for encapsulating the semiconductor element, wherein the molding compound comprises a metal oxide.

The present invention further provides a fabrication method of a semiconductor package, which comprises the steps of: disposing at least a semiconductor element on a substrate body; and forming a molding compound on the substrate body to encapsulate the semiconductor element, wherein the molding compound comprises a metal oxide.

In the above-described semiconductor package and the fabrication method thereof, the semiconductor package can be a wire-bonding type package, a flip-chip type package, a hybrid type package, an embedded type package or a wafer level package.

In the above-described semiconductor package and the fabrication method thereof, the substrate body can be electrically connected to the semiconductor element, and the semiconductor element can be an active element or a passive element.

In the above-described semiconductor package and the fabrication method thereof, the metal oxide can be at least one selected from the group consisting of iron oxide such as Fe₂O₃, manganese oxide such as Mn₃O₄ and zinc oxide such as ZnO.

The present invention further provides a molding compound, which comprises: a polymer resin; and a metal oxide selected from the group consisting of iron oxide, manganese oxide and zinc oxide.

The iron oxide can be Fe₂O₃. The manganese oxide can be Mn₃O₄ and the zinc oxide can be ZnO.

The polymer resin can be an epoxy resin.

Therefore, the present invention effectively prevents electromagnetic interference by forming a molding compound that has a high insulation impedance and a high heat dissipating rate and can suppress electromagnetic interference instead of using a conventional metal shield, thus simplifying the fabrication and assembly of the semiconductor package.

Further, since the molding compound in a molding process does not need to pass through a perforated metal shield as in the prior art, the present invention prevents turbulence from occurring in the molding compound. Therefore, the present invention avoids generation of voids in the molding compound and hence prevents a popcorn effect from occurring during a subsequent heating process.

### BRIEF DESCRIPTION OF DRAWINGS

FIG. 1 is a cutaway view of a conventional semiconductor package;

FIGS. 2A and 2B are schematic cross-sectional views showing a fabrication method of a semiconductor package according to an embodiment of the present invention; and

FIGS. 3 to 7 are schematic cross-sectional views showing semiconductor packages of other embodiments of the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “upper”, “a” etc. are merely for illustrative purposes and should not be construed to limit the scope of the present invention.

FIGS. 2A and 2B are schematic cross-sectional views showing a fabrication method of a semiconductor package 2 according to an embodiment of the present invention. The semiconductor package 2 is a wire-bonding type package.

Referring to FIG. 2, a semiconductor element 21 is disposed on a substrate body 20 and electrically connected to the substrate body 20 through a plurality of bonding wires 22.

In the present embodiment, the substrate body 20 is a packaging substrate such as a circuit board, a metal plate or a ceramic plate. The substrate body 20 has circuits (not shown) formed thereon and electrically connected to the bonding wires 22.

The semiconductor element 21 is an active element or a passive element.

Referring to FIG. 2B, a molding compound 23 is formed on the substrate body 20 for encapsulating the semiconductor element 21. The molding compound 23 contains a metal oxide. The molding compound 23 is then cured to form an encapsulant.

In the present embodiment, the metal oxide is an iron oxide such as Fe₂O₃. The metal oxide can further contain manganese and zinc oxide such as Mn₃O₄ and ZnO. For example, sintered oxides of Mn, Zn and Fe are pulverized and then mixed with a polymer resin such as an epoxy resin to form a molding compound that has a high insulation impedance and a high heat dissipating rate and can suppress electromagnetic interference.

Therefore, the present invention shields the semiconductor element 21 from external electromagnetic interference by forming the molding compound 23 that contains a metal oxide so as to have a high insulation impedance and a high heat dissipating rate and is capable of suppressing electromagnetic interference, thereby preventing abnormal operation of the semiconductor package 2. Further, the present invention dispenses with the conventional metal shield and thereby simplifies the fabrication and assembly of the semiconductor package 2. Therefore, the present invention facilitates the mass production of the semiconductor package.

Furthermore, since the molding compound 23 in a molding process does not need to pass through a perforated metal shield as in the prior art, the present invention prevents turbulence from occurring in the molding compound 23. As such, the present invention avoids generation of voids in the molding compound 23 and hence prevents a popcorn effect from occurring during a subsequent heating process.

FIGS. 3 to 7 are schematic cross-sectional views showing semiconductor packages 3, 4, 5, 6, 7 of different embodiments of the present invention.

Referring to FIG. 3, the semiconductor package 2 is a flip-chip type package. The substrate body 20 is a packaging substrate and the semiconductor element 31 is electrically connected to the substrate body 20 through a plurality of conductive bumps 32.

Referring to FIG. 4, the semiconductor package 4 is a hybrid type package. The substrate body 20 is a packaging substrate and a plurality of semiconductor elements 41a, 41b are stacked on the substrate body 20. The lower semiconductor element 41a is electrically connected to the substrate body 20 through a plurality of conductive bumps 42a and the upper semiconductor element 41b is electrically connected to the substrate body 20 through a plurality of bonding wires 42b.

Referring to FIG. 5, the semiconductor package 5 is a wire-bonding type package. The substrate body 50 is a lead frame and the semiconductor element 21 is electrically connected to the substrate body 50 through a plurality of bonding wires 22.

Referring to FIG. 6, the semiconductor package 6 is a QFN (Quad Flat No Leads) wire-bonding type package. The substrate body 60 is a lead frame or a packaging substrate and the semiconductor element 21 is electrically connected to the substrate body 60 through a plurality of bonding wires 22.

Referring to FIG. 7, the semiconductor package 7 is a wafer level package (WLP) or an embedded type package. The substrate body 70 has a multi-layer circuit structure and is electrically connected to the semiconductor element 71 through a plurality of conductive vias.

The present invention further provides a semiconductor package 2, 3, 4, 5, 6, 7, which has: a substrate body 20, 50, 60, 70; a semiconductor element 21, 31, 41a, 41b, 71 disposed on the substrate body 20, 50, 60, 70; and a molding compound 23 encapsulating the semiconductor element 21, 31, 41a, 41b, 71.

The semiconductor package 2, 3, 4, 5, 6, 7 is a wire-bonding type package, a flip-chip package, a hybrid type package or a wafer level package.

The substrate body 20, 50, 60, 70 is electrically connected to the semiconductor element 21, 31, 41a, 41b, 71.

The semiconductor element 21, 31, 41a, 41b, 71 is an active element or a passive element.

The molding compound 23 contains a metal oxide.

In particular, the molding compound 23 contains a polymer resin such as an epoxy resin and a metal oxide such as iron oxide (Fe₂O₃), manganese oxide (Mn₃O₄) and zinc oxide (ZnO).

Therefore, based on the characteristics of the molding compound, the present invention achieves an EMI shielding effect without the need of a conventional metal shield, thereby simplifying the fabrication of the semiconductor package.

Further, since the molding compound in a molding process does not need to pass through a perforated metal shield as in the prior art, the present invention avoids generation of voids in the molding compound and hence prevents a popcorn effect from occurring.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a substrate body;
at least a semiconductor element disposed on the substrate body; and
a molding compound formed on the substrate body for encapsulating the semiconductor element, wherein the molding compound comprises a metal oxide.

2. The package of claim 1, being a wire-bonding type package, a flip-chip type package, a hybrid type package, an embedded type package or a wafer level package.

3. The package of claim 1, wherein the substrate body is electrically connected to the semiconductor element.

4. The package of claim 1, wherein the semiconductor element is an active element or a passive element.

5. The package of claim 1, wherein the metal oxide is at least one selected form the group consisting of iron oxide, manganese oxide and zinc oxide.

6. The package of claim 5, wherein the iron oxide is Fe₂O₃.

7. The package of claim 5, wherein the manganese oxide is Mn₃O₄.

8. The package of claim 5, wherein the zinc oxide is ZnO.

9. The package of claim 1, wherein the metal oxide is in powder form.

10. A fabrication method of a semiconductor package, comprising the steps of:
disposing at least a semiconductor element on a substrate body; and
forming a molding compound on the substrate body to encapsulate the semiconductor element, wherein the molding compound comprises a metal oxide.

11. The method of claim 10, wherein the semiconductor package is a wire-bonding type package, a flip-chip type package, a hybrid type package, an embedded type package or a wafer level package.

12. The method of claim 10, wherein the substrate body is electrically connected to the semiconductor element.

13. The method of claim 10, wherein the semiconductor element is an active element or a passive element.

14. The method of claim 10, wherein the metal oxide is at least one selected from the group consisting of iron oxide, manganese oxide and zinc oxide.

15. The method of claim 14, wherein the iron oxide is Fe₂O₃.

16. The method of claim 14, wherein the manganese oxide is Mn₃O₄.

17. The method of claim 14, wherein the zinc oxide is ZnO.

18. The method of claim 10, wherein the metal oxide is in powder form.

19. A molding compound, comprising:
a polymer resin; and
a metal oxide selected from the group consisting of iron oxide, manganese oxide and zinc oxide.

20. The compound of claim 19, wherein the iron oxide is Fe₂O₃.

21. The compound of claim 19, wherein the manganese oxide is Mn₃O₄.

22. The compound of claim 19, wherein the zinc oxide is ZnO.

23. The compound of claim 19, wherein the metal oxide is in powder form.

24. The compound of claim 19, wherein the polymer resin is an epoxy resin.
